(19) United States
(12) Patent Application Publication
(10) Pub. No.: US 2013/0170898 A1
(43) Pub. Date: Jul. 4, 2013

(54) MOUNTING APPARATUS FOR COMPUTER KEYBOARD

(71) Applicant: QIANG-WU DAI, Shenzhen City (CN)

(72) Inventor: QIANG-WU DAI, Shenzhen City (CN)

(21) Appl. No.: 13/660,330

(22) Filed: Oct. 25, 2012

(30) Foreign Application Priority Data
Dec. 29, 2011 (CN) 201110450146.2

(51) Int. Cl. H05K 7/14

(52) U.S. Cl. 403/326

(57) ABSTRACT

A mounting apparatus for a keyboard includes a supporting member and a receiving member. The supporting member includes a supporting plate and a plurality of resilient blocks located on the supporting plate. The receiving member is attached to the supporting plate and includes a receiving portion configured to receive the keyboard and defining a plurality of receiving holes. Each of the plurality of resilient blocks is received in each of the plurality of receiving holes. Each of the plurality of resilient blocks extends through each of the plurality of receiving holes to abuts the keyboard, for preventing the keyboard from disengagement the receiving portion. Each of the plurality of resilient blocks is resiliently deformable to disengage from the keyboard, to release the keyboard.

### BACKGROUND

1. Technical Field

The present disclosure relates to mounting apparatuses, and particularly to a mounting apparatus for a computer keyboard.

2. Description of Related Art

A typical personal computer includes a keyboard and a base. The keyboard may be attached to the base with screws. A tool, such as a screwdriver, is needed to fasten or unfasten the screws to assemble or disassemble the keyboard. The process to assemble or dismounting apparatus the keyboard is very laborious and time-consuming.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of a mounting apparatus and a keyboard.

FIG. 2 is similar to FIG. 1, but viewed from another aspect.

FIG. 3 is an enlarged view of a circled portion III of FIG. 1.

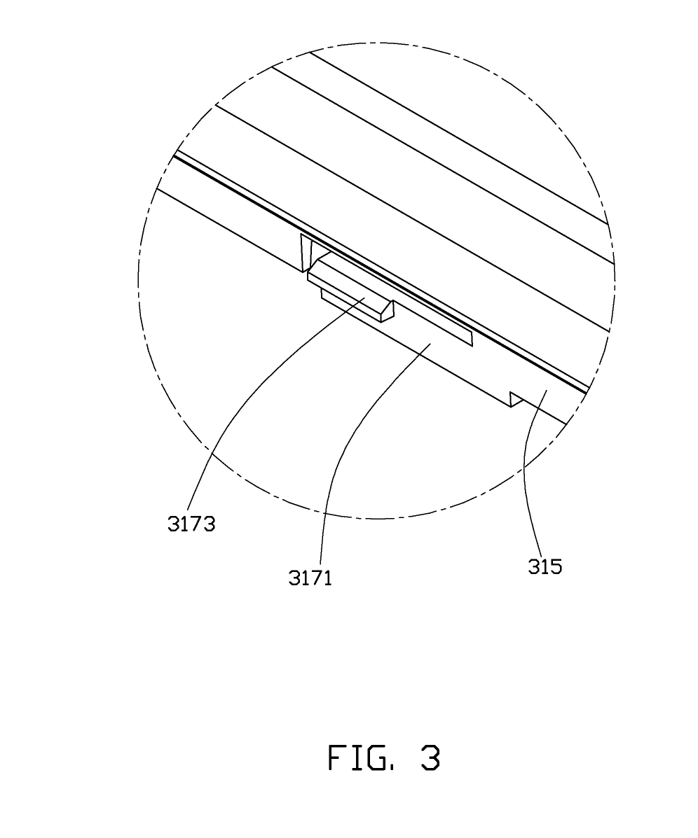

FIG. 4 is an isometric, cutaway exploded view of a supporting member of FIG. 1.

FIG. 5 is an enlarged view of a circled portion V of FIG. 1.

FIG. 6 is an assembled view of the mounting apparatus and the keyboard of FIG. 1.

FIG. 7 is a cutaway, cross-sectional view of the mounting board and the keyboard of FIG. 6, taken along the line VII-VII.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

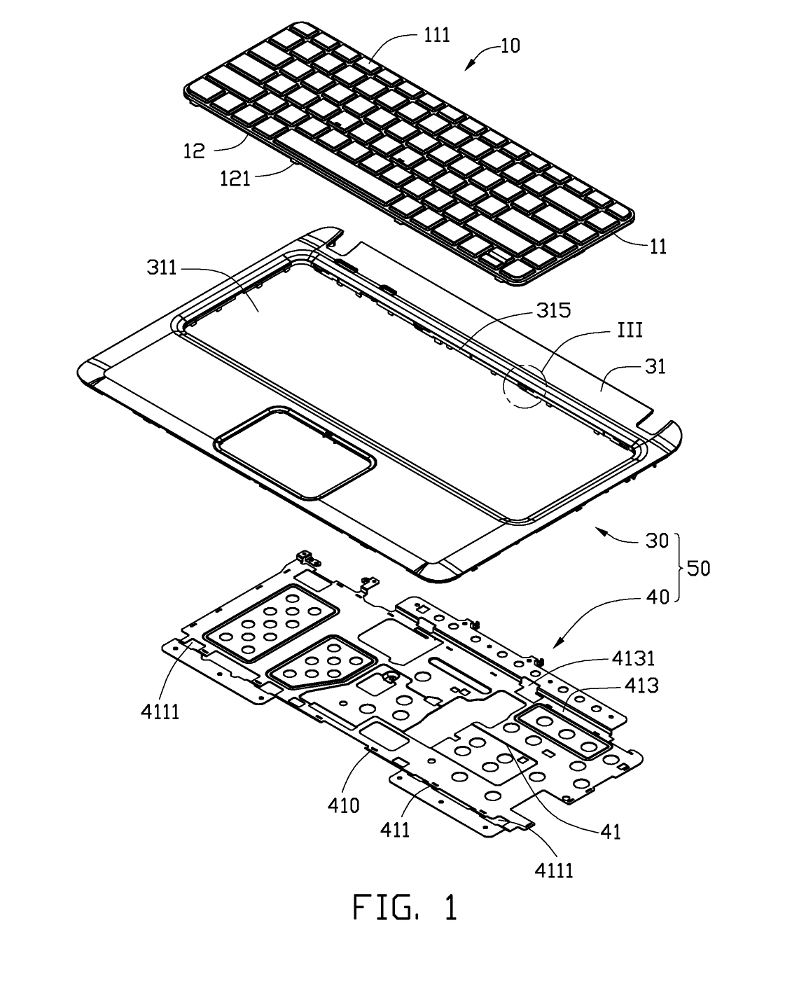

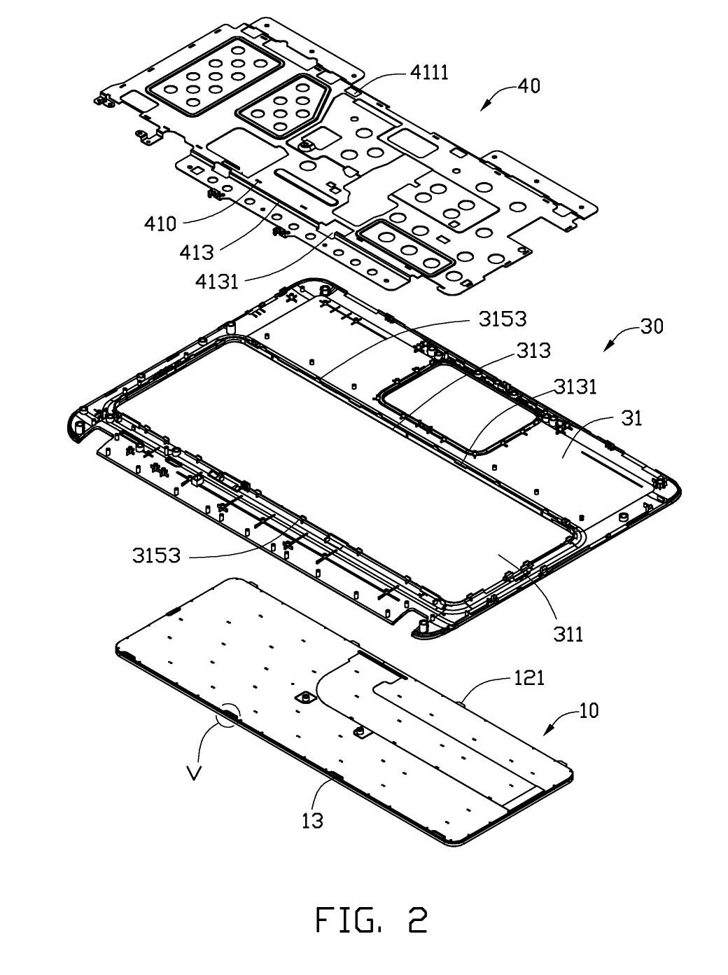

FIG. 1-2 illustrate an embodiment of a mounting apparatus configured to secure a keyboard 10.

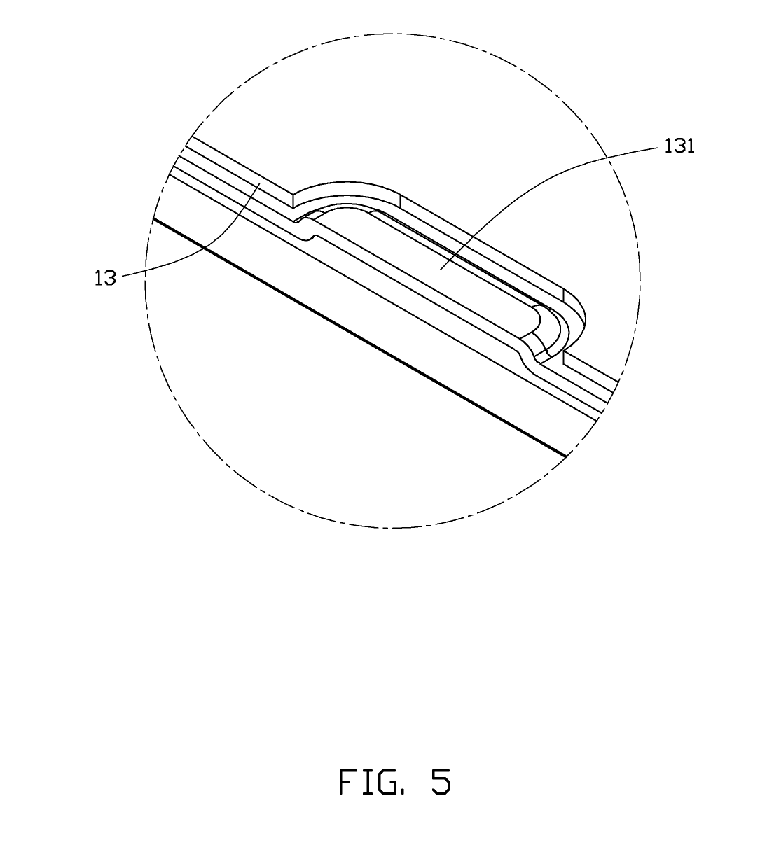

The keyboard 10 includes a bezel 11. A plurality of keys 111 are located on the bezel 11. The bezel 11 has a first edge 12 and a second edge 13 opposite to the first edge 12. In one embodiment, the bezel 11 is substantially rectangular. Four inserting tabs 121 extend from the first edge 12. The second edge 13 defines four latch slots 131(shown in FIG. 5).

The mounting apparatus includes a base 50. The base 50 includes a supporting member 30 and a receiving member 40 attached to the supporting member 30.

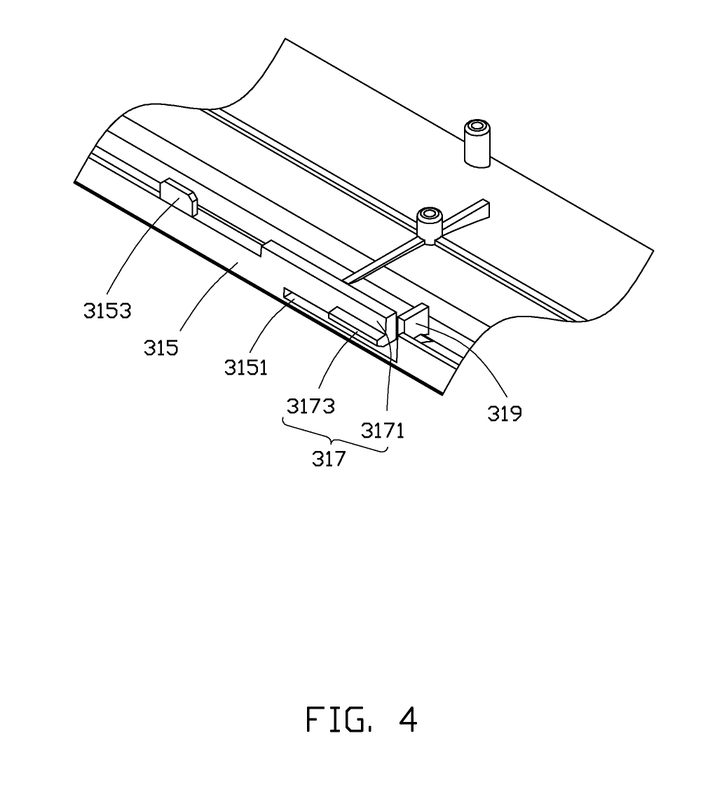

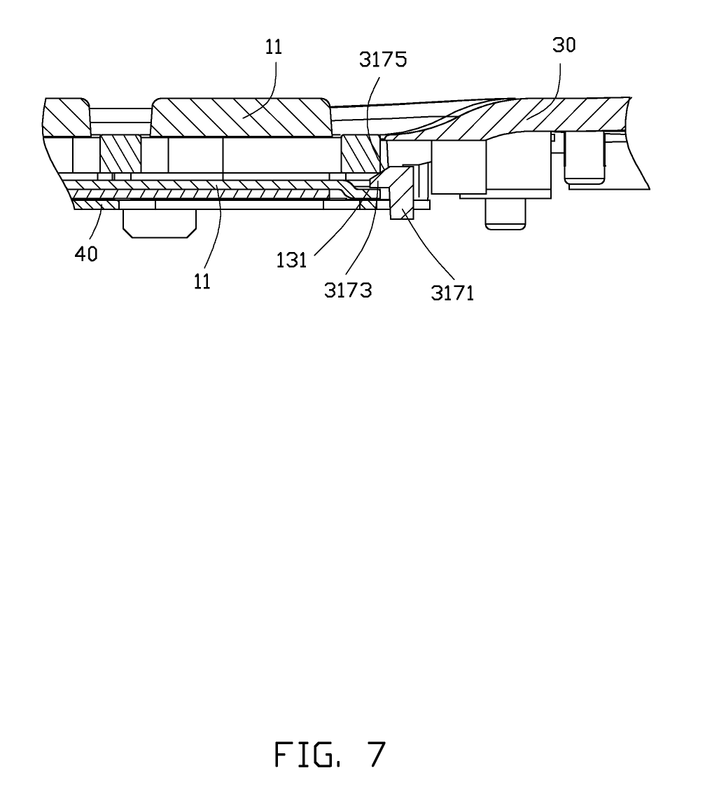

The supporting member 30 includes a supporting plate 31. The supporting plate 31 defines an opening 311 for installing the keyboard 10. The opening 311 is substantially rectangular, for example. A first flange 313 and a second flange 315 extend downwards from two opposite edges of the opening 311. The first flange 313 defines four through holes 3131 corresponding to the fourth inserting tabs 121 of the keyboard 10. Referring to FIG. 4, four resilient blocks 317 are located on the second flange 13. Each of the resilient blocks 317 includes a resilient portion 3171 and a latch portion 3173. A slit 3151 is defined between the resilient portion 3171 and the supporting plate 31. The resilient portion 3171 extends from the second flange 13 and has an extending direction that is substantially parallel to the second flange 13. The latch portion 3173 of each of the four resilient blocks 317, towards the opening 311, is located on one side of the resilient portion 3171 and adjacent to a free end of the resilient portion 3171. The latch portion 3173 of each of the four resilient blocks 317 has an oblique-guiding surface 3175 (shown in FIG. 7). A plurality of positioning tabs 3153 are located on the supporting plate 31 and arranged around the opening 311. A plurality of blocking pieces 319, corresponding to the resilient blocks 317, are located on the supporting plate 31. Each blocking piece 319 and the latch portion 3173 of each of the four resilient blocks 317 are located on opposite sides of the resilient portion 3171 and can block the resilient portion to be over-deformed.

The receiving member 40 includes a receiving portion 41. The receiving portion 41 includes a first side wall 411 and a second side wall 413 opposite to the first side wall 411. The first side wall 411 defines four latch holes 4111 corresponding to the four inserting tabs 121. The second side wall 413 defines four receiving holes 4131 corresponding to the four resilient blocks 317. The receiving portion 41 defines a plurality of positioning holes 410 corresponding to the plurality of positioning tabs 3153.

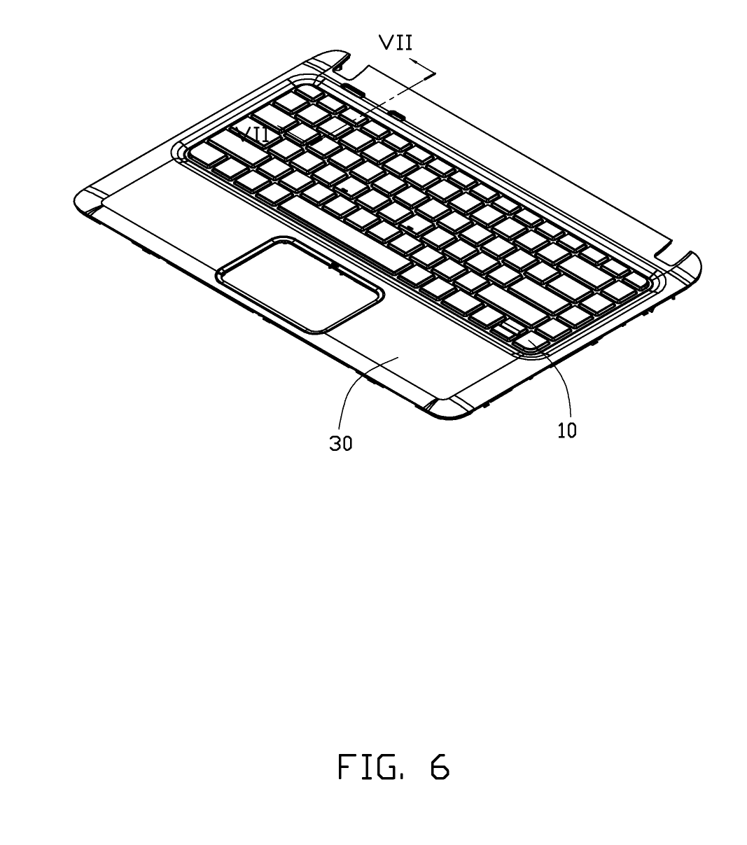

Referring to FIGS. 6 and 7, to install the receiving member 40, the receiving member 40 is attached to the supporting member 30. Each of plurality of positioning tabs 3153 is engaged in each of the plurality of positioning holes 410. Each latch hole 4111 is aligned with each through hole 3131. Each resilient block 317 is positioned in each receiving hole 4131, and the latch portion 3173 extends through the receiving hole 4131. The receiving member 40 is thereby installed on the supporting member 30.

To install the keyboard 10, each inserting tab 121 is inserted into each through hole 3131 and each latch hole 4111. The keyboard 10 is moved to the second edge 13 along the guiding surface 3175. The latch portion 3173 is moved back to deform the resilient portion 3171, until the latch portion 3173 is aligned with the latch slot 131. The keyboard 10 is thereby received in the receiving portion 41. The resilient portion 3171 rebounds to engage the latch portion 3173 in the latch slot 131 and block the keyboard, to prevent the keyboard 10 disengagement from the receiving portion 41.

To detached the keyboard 10, the latch portion 3173 is pushed to disengage from the latch slot 131. The keyboard 10 is released and easily detached from the base 50.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A mounting apparatus for a keyboard comprising:
a supporting member, the supporting member comprising a supporting plate and a plurality of resilient blocks located on the supporting plate; and
a receiving member attached to the supporting plate, the receiving member comprising a receiving portion, that is configured to receive the keyboard, and defines a plurality of receiving holes;
wherein each of the plurality of resilient blocks is received in each of the plurality of receiving holes; each of the plurality of resilient blocks extends through each of the plurality of receiving holes to press the keyboard, for preventing the keyboard from disengaging from the receiving portion; and each of the plurality of resilient blocks is resiliently deformable to disengage from the keyboard, to release the keyboard.

2. The mounting apparatus of claim 1, wherein each of the plurality of resilient blocks comprises a resilient portion and a latch portion, located on the resilient portion; the latch portion abuts the keyboard; and the resilient portion is resiliently deformable, to disengage the latch portion from the keyboard.

3. The mounting apparatus of claim 2, wherein the supporting member further comprises a flange connected to the supporting plate, the flange is substantially perpendicular to the supporting plate, and the plurality of resilient blocks are located on the flange.

4. The mounting apparatus of claim 2, wherein a slit is defined between the resilient portion and the supporting plate.

5. The mounting apparatus of claim 3, wherein the resilient portion extends from the flange and has an extension direction parallel to the flange.

6. The mounting apparatus of claim 2, wherein the supporting member further comprises a plurality of blocking pieces, the plurality of blocking pieces are located on the supporting plate, and each of the plurality of blocking pieces and the latch portion are located on opposite sides of the resilient portion.

7. The mounting apparatus of claim 2, wherein the latch portion has a guiding surface, and the guiding surface is oblique.

8. The mounting apparatus of claim 6, wherein each of the plurality of blocking pieces is substantially perpendicular to the resilient portion.

9. A mounting apparatus for a keyboard comprising:
a supporting member, the supporting member comprising a supporting plate and a plurality of resilient blocks located on the supporting plate; each of the resilient blocks comprising a resilient portion and a latch portion located on the resilient portion; and
a receiving member attached to the supporting plate, the receiving member comprising a receiving portion, that is configured to receive the keyboard, and defines a plurality of receiving holes;
wherein each of the plurality of resilient blocks is received in each of the plurality of receiving holes; the latch portion extends through each receiving hole to abuts the keyboard, for preventing the keyboard from disengagement from the receiving portion;
and the resilient portion is resiliently deformable to disengage the latch portion from the keyboard, to release the keyboard.

10. The mounting apparatus of claim 9, wherein the supporting member further comprises a flange connected to the supporting plate, the flange is substantially perpendicular to the supporting plate, and the plurality of the resilient blocks are located on the flange.

11. The mounting apparatus of claim 9, wherein a slit is defined between the resilient portion and the supporting plate.

12. The mounting apparatus of claim 10, wherein the resilient portion extends from the flange and has an extension direction parallel to the flange.

13. The mounting apparatus of claim 9, wherein the supporting member further comprises a plurality of blocking pieces, the plurality of blocking pieces are located on the supporting plate, and each of the plurality of blocking pieces and the latch portion are located on opposite sides of the resilient portion.

14. The mounting apparatus of claim 9, wherein the latch portion has a guiding surface, and the guiding surface is oblique.

15. The mounting apparatus of claim 13, wherein each of the plurality of blocking pieces is substantially perpendicular to the resilient portion.
